(19) United States
(12) Patent Application Publication
(10) Pub. No.: US 2026/0196442 A1
(43) Pub. Date: Jul. 9, 2026

(54) CONTROL SYSTEM FOR DYNAMIC STEPPER MOTOR

(71) Applicant: Applied Materials, Inc., Santa Clara, CA (US)

(72) Inventors: STEPHEN COOL, Santa Clara, CA (US); JOSHUA JONES, Penfield, NY (US); AUNG TOE, Newton, MA (US); ERIC WELCH, Santa Clara, CA (US)

(21) Appl. No.: 19/012,726

(22) Filed: Jan. 7, 2025

(51) Int. Cl. H01J 37/32; H02P 8/22; H02P 21/13; H02P 21/18

(52) U.S. Cl. CPC H01J 37/32183; H01J 37/32899; H02P 8/22; H02P 21/13; H02P 21/18

(57) ABSTRACT

Embodiments described herein relate to an apparatus that includes a stepper motor, a driver chip communicatively coupled to the stepper motor, an encoder communicatively coupled to the stepper motor, and a feedback controller communicatively coupled to the driver chip and the encoder. In an embodiment, the feedback controller includes a state space plant configured to receive a control signal and generate a vector including a position and velocity of the stepper motor. In an embodiment, the feedback controller further includes a pulse width modulation (PWM) converter configured to receive the vector and output a first PWM signal corresponding to a number of steps to drive the stepper motor and a second PWM signal corresponding to a direction of the number of steps of the stepper motor. In an embodiment, the feedback controller further includes a Luenberger observer configured to receive a feedback signal from the encoder.

### BACKGROUND

### 1) Field

Embodiments relate to the field of dynamic stepper motor control systems.

### 2) Description of Related Art

In plasma processing environments, impedance matches are used to match an impedance between a power source and a plasma load. A variable impedance match is often used to adjust the impedance in order to match a dynamic plasma load. Due to rapidly changing conditions within the plasma chamber, the variable impedance match needs to have a quick response in order to provide efficient power delivery to the plasma load (e.g., with minimal power reflection back to the power source).

Variable impedance matches are often controlled by adjusting a capacitance of one or more capacitors and/or an inductance of one or more inductors provided within the variable impedance match. The capacitors and/or inductors are adjusted with a motor. Servo motors offer good response times, but servo motors are expensive. Accordingly, stepper motors are typically used as a cost-effective solution. However, the feedback control for stepper motors is limited. For example, trapezoid models are currently used. Such models control velocity of the stepper motor at discontinuous rates. This limits the amount of acceleration of the motors and inhibits performance under dynamic conditions.

### SUMMARY

Embodiments described herein relate to an apparatus that includes a stepper motor, a driver chip communicatively coupled to the stepper motor, an encoder communicatively coupled to the stepper motor, and a feedback controller communicatively coupled to the driver chip and the encoder. In an embodiment, the feedback controller includes a state space plant configured to receive a control signal and generate a vector including a position and velocity of the stepper motor. In an embodiment, the feedback controller further includes a pulse width modulation (PWM) converter configured to receive the vector and output a first PWM signal corresponding to a number of steps to drive the stepper motor and a second PWM signal corresponding to a direction of the number of steps of the stepper motor. In an embodiment, the feedback controller further includes a Luenberger observer configured to receive a feedback signal from the encoder.

Embodiments described herein relate to an apparatus that includes a plasma chamber, a power source electrically coupled to the plasma chamber, an impedance match with a variable passive electrical component, where the impedance match is electrically coupled between the plasma chamber and the power source, and a stepper motor coupled to the variable passive electrical component. In an embodiment, the stepper motor is configured to be controlled by a motor controller, and the motor controller includes a feedback control algorithm with a state space plant with a Luenberger observer.

Embodiments described herein relate to an apparatus that includes a field programmable gate array (FPGA) configured to implement a state space plant configured to receive a control signal and generate a vector including a position and a velocity of a stepper motor, where the state space plant is fed a feedback input that is informed by a Luenberger observer that is stored in a non-transitory machine-readable medium coupled to the FPGA. In an embodiment, the apparatus further includes a pulse width modulation (PWM) converter electrically coupled to the FPGA, where the PWM converter is configured to receive the vector and output a first PWM signal corresponding to a number of steps to drive the stepper motor and a second PWM corresponding to a direction of the number of steps of the stepper motor.

### BRIEF DESCRIPTION OF THE DRAWINGS

FIG. 1A is plot of velocity over time for a stepper motor that is controlled with a trapezoid model, in accordance with an embodiment.

FIG. 1B is a plot of velocity over time for a stepper motor that is controlled with a state space model with pole placement feedback and a Luenberger observer to provide a continuous velocity curve, in accordance with an embodiment.

FIG. 2 is a schematic illustration of a control system with a controller that implements a feedback algorithm that includes a state space model with pole placement feedback and a Luenberger observer to control a stepper motor, in accordance with an embodiment.

FIG. 3A is a schematic illustration of a plasma processing tool with an impedance match that is controlled with a controller that implements a feedback algorithm that includes a state space model with pole placement feedback and a Luenberger observer to control a stepper motor, in accordance with an embodiment.

FIG. 3B is a schematic illustration of a plasma processing system with a plurality of plasma chambers and a plurality of corresponding impedance matches that are each controlled with a controller that implements a feedback algorithm that includes a state space model with pole placement feedback and a Luenberger observer to control a stepper motor, in accordance with an embodiment.

FIG. 4 is a schematic illustration of a power delivery system with a power source, a load, and a variable impedance match with a stepper motor that is controlled with a controller that implements a feedback algorithm that includes a state space model with pole placement feedback and a Luenberger observer to control a stepper motor, in accordance with an embodiment.

FIG. 5 is a schematic illustration of a plasma processing tool with an impedance match that is controlled with a controller that implements a feedback algorithm that includes a state space model with pole placement feedback and a Luenberger observer to control a stepper motor, in accordance with an embodiment.

FIG. 6 is a flow diagram for impedance matching power that is delivered to a load with a stepper motor that is controlled with a controller that implements a feedback algorithm that includes a state space model with pole placement feedback and a Luenberger observer to control a stepper motor, in accordance with an embodiment.

FIG. 7 illustrates a block diagram of an exemplary computer system that may be used in conjunction with a processing tool, in accordance with an embodiment.

### DETAILED DESCRIPTION

Embodiments described herein include dynamic stepper motor control systems with pole placement feedback and a Luenberger observer. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

The embodiments illustrated and discussed in relation to the figures included herein are provided for the purpose of explaining some of the basic principles of the disclosure. However, the scope of this disclosure covers all related, potential, and/or possible, embodiments, even those differing from the idealized and/or illustrative examples presented. This disclosure covers even those embodiments which incorporate and/or utilize modern, future, and/or as of the time of this writing unknown, components, devices, systems, etc., as replacements for the functionally equivalent, analogous, and/or similar, components, devices, systems, etc., used in the embodiments illustrated and/or discussed herein for the purpose of explanation, illustration, and example.

As noted above, impedance matching in power delivery systems (e.g., RF systems, microwave systems, etc.) requires precise feedback in order to prevent power from reflecting back from the load to the power source. While servo motors provide quick response times, the cost of servo motors can be too high for some application spaces. Accordingly, stepper motors are often used to control the variable elements (e.g., capacitors) of the impedance match. While the speed and accuracy of stepper motors is generally not as good as a servo motor, control systems can be obtained that allow for stepper motors to provide acceptable performance for some applications.

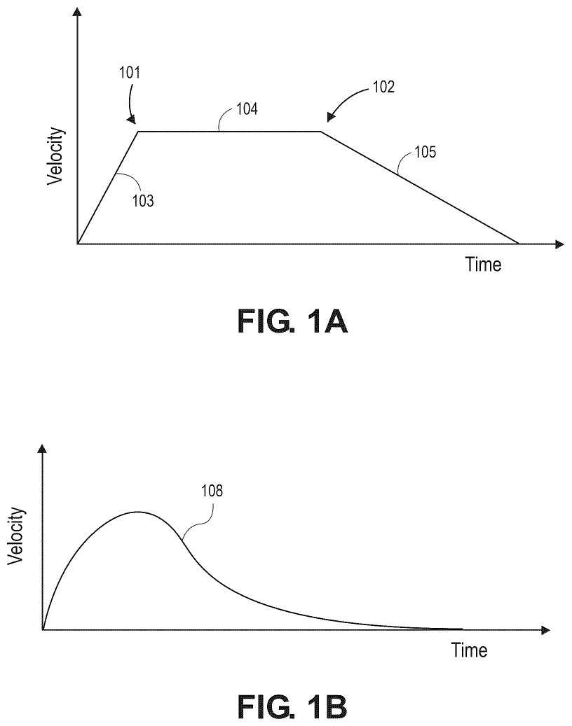

Generally, stepper motors for impedance matching systems are controlled with a trapezoid model to control the velocity of the stepper motor. The trapezoid model provides a trajectory that includes a first acceleration to reach a desired velocity during a first duration, a constant velocity during a second duration, and a second acceleration during a third duration in order to stop the stepper motor at a desired location. An example of one such trajectory is shown in FIG. 1A.

As shown in FIG. 1A, a first portion 103 of the trajectory has a positive acceleration (e.g., a positive slope) to allow the stepper motor to reach the constant velocity at a second portion 104. Thereafter, the third portion 105 includes a negative acceleration (e.g., a negative slope) to stop the stepper motor at a desired location. However, FIG. 1A illustrates that there are discontinuities along the trajectory. For example, a first discontinuity 101 is provided at the transition from the first portion 103 of the trajectory to the second portion 104 of the trajectory, and a second discontinuity 102 is provided at the transition from the second portion 104 of the trajectory to the third portion 105 of the trajectory.

The discontinuities 101 and 102 represent discontinuous higher order dynamics that can lead to a jerking response. This discontinuous behavior leads to lower stable peak velocities and requires a longer time to reach a target position. Further, additional logic is needed to calculate new trapezoids when the target position is dynamic. The use of additional logic leads to sub-optimal trajectories. Accordingly, the use of stepper motors with trapezoidal models may not provide the desired performance for dynamic impedance matching applications.

Accordingly, embodiments disclosed herein may use a stepper motor control system that provides a continuous velocity profile, as shown in FIG. 1B. For example, the velocity trajectory 108 has a smooth curve with a peak and a smooth transition back to a stop. The continuous profile allows for trajectories that have faster accelerations and higher velocities than are possible with the trapezoidal models. Particularly, the lack of discontinuities allows for a smoother performance. In contrast, the trapezoidal models rely on smaller accelerations and velocities in order to minimize the negative effects of the jerking conditions that arise from the discontinuities within the trajectory. Therefore, embodiments disclosed herein may be useful for high performance impedance matching use cases, such as in RF plasma systems. Though, it is to be appreciated that the stepper motor control systems described herein may be used in conjunction with any application that uses a stepper motor.

In an embodiment, the stepper motor control system may include the use of an algorithm that operates in the state space. Further, the algorithm may be optimized through the use of one or both of a pole placement feedback input and/or the inclusion of a Luenberger observer. In an embodiment, the algorithm may generate signals that are converted into pulse width modulation (PWM) signals that are delivered to the stepper motor (e.g., through a stepper motor driver chip). In an embodiment, an encoder of the stepper motor may provide feedback to the Luenberger observer of the algorithm. A subsequent calculation is made by the algorithm to determine a new acceleration for the stepper motor. As this feedback processes over time, the acceleration is continuously updated in order to provide the continuous trajectory.

In a particular embodiment, the stepper motor control system may be used in an RF plasma tool, such as an RF plasma chamber for semiconductor processing. In such an embodiment, an RF power source delivers RF power to a chamber in order to generate a plasma within the chamber. A variable impedance match may be provided along the electrical path between the RF power source and the chamber. In an embodiment, the variable impedance match may include one or more tuning elements (e.g., variable capacitors) that are controlled by a stepper motor. In an embodiment, the stepper motor is controlled by the stepper motor control system using an algorithm such as any of the state space algorithms described in greater detail herein.

The use of a state space algorithm also allows for easy scaling to control multiple motors working in parallel with different motor dynamics. Such a scaled system may be particularly beneficial in a semiconductor processing environment where a plurality of plasma chambers are powered by a single RF power source, and the RF power is split to the plurality of plasma chambers by a power splitter. In such an embodiment, the impedance match for each plasma chamber may be controlled by different stepper motors that are each under the control of the stepper motor control system.

More generally, embodiments disclosed herein allow for actuator motors that are orders of magnitude less expensive than servo motors while still maintaining peak performance (e.g., fast and accurate actuation). That is, less expensive stepper motors can be controlled in a manner that allows for servo motor-like performance. The control systems disclosed herein are also adaptable to many application spaces, such as deployment in variable impedance matches for semiconductor manufacturing, communication systems, or the like. The encoder and feedback process using a state space model with pole placement feedback and a Luenberger observer also allows for easy tuning.

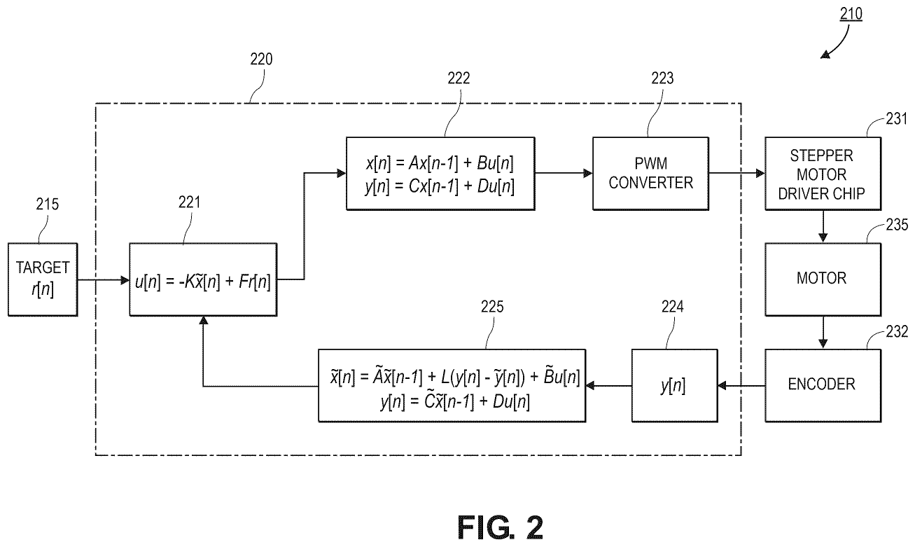

Referring now to FIG. 2, a schematic illustration of a stepper motor system 210 is shown, in accordance with an embodiment. In an embodiment, the stepper motor system 210 may comprise a motor controller 220. In an embodiment, the motor controller 220 may be implemented on a field programmable gate array (FPGA). The motor controller 220 may implement a feedback control algorithm. In a particular embodiment, the feedback control algorithm is implemented in a state space. A state space may refer to a mathematical model of the physical system of the stepper motor 235 that is being controlled by the motor controller 220.

In an embodiment, a target 215 is provided as an input to the control loop. The target 215 may represent a desired angular position r[n] of the stepper motor 235 in some embodiments with r being the angular position and n being the discrete point in time the system is being evaluated. The target 215 is fed into a control block 221 that is used to calculate an acceleration u[n] that is needed to drive the stepper motor 235 to the target 215. In the control block 221, the variables K and F may be gains that are used to control a shape of the trajectory from the current position of the stepper motor 235 to the target 215 position of the stepper motor 235. The variable \tilde{x}[n] may be the current angular position of the stepper motor 235. Accordingly, the control block 221 defines a linear model with a simple calculation of input acceleration u[n]=−K\tilde{x}[n]−Fr[n].

In an embodiment, the acceleration u[n] is fed into a plant 222 of the motor controller 220. The plant 222 may include equations that provide a notional expectation of how the stepper motor behaves based on physics-based equations (e.g., first order and/or second order dynamics of the system). In an embodiment, the plant 222 may be the state space portion of the motor controller. In some instances, the plant 222 may be considered a “phantom” state space plant 222, since the plant 222 may be implemented in software (e.g., through an algorithm) as opposed to relying on a physical system. The equations within the plant 222 may include gains (e.g., A, B, C, D) that are used to control a shape of the trajectory of the stepper motor between a first position and a second position. For example, the trajectory may have a continuous curve with one or more of the slope (e.g., acceleration), peaks (e.g., peak velocity), rise time, settling time of motion, and/or the like controllable through choice of the different gain values. In some embodiments, the gain values can be calculated mathematically, which can enable a zero-steady state error condition. In an embodiment, the state space plant 222 enables an accurate approximation of a discrete model for a discontinuous system (such as a stepper motor 235 that moves in discrete steps and is non-continuous).

In an embodiment, x[n] is a vector that represents a position and velocity of the stepper motor, and y[n] is an encoder measurement that is provided as a feedback input. In some embodiments, the control and selection of the gain values may include a pole placement feedback process. Placing the poles may be beneficial since the locations of the poles correspond to eigenvalues of the system, and the eigenvalues may be used to define the characteristics of the response of the system (e.g., the shape of the trajectory). That is, the placement of the poles may be done with a mathematical technique, which yields a more stable system. In traditional control loop methodologies (such as proportional-integral-derivative (PID) control) complicated methods for placing poles of the system are used, and this can lead to the generation of control loops that are difficult to control. Additionally, the internal states of a state space model may be estimated at all times, while a PID control loop does not have such capabilities.

In an embodiment, the motor controller 220 may further comprise a PWM converter 223. The PWM converter 223 may include circuitry for converting signals from the plant 222 to a PWM signal that is used by the stepper motor 235. PWM signals are beneficial for stepper motors 235 since the PWM signal enables accurate position and speed control of the stepper motor 235 through control of the duration of electrical pulses. In an embodiment, the PWM converter 223 may output a pair of PWM signals to the stepper motor 235. For example, a first PWM signal may be used to control the motor steps, and a second PWM signal may be used to control the direction of the stepper motor 235.

In an embodiment, the PWM signals are sent to a stepper motor driver chip 231. The stepper motor driver chip 231 may be used to control magnets within the motor 235 in order to change the angular position of the stepper motor 235. In the illustrated embodiment, the stepper motor driver chip 231 is shown as a discrete component from the stepper motor 235. Though, in other embodiments, the stepper motor driver chip 231 may be integrated with the stepper motor 235 as a single component. In an embodiment, an encoder 232 may record the positioning of the stepper motor 235 and report the positioning as feedback 224 back to the motor controller 220. Similar to the stepper motor driver chip 231, the encoder 232 may be integrated with the stepper motor 235 as a single component. It is to be appreciated that the use of such a state space-based motor control 220 also allows for the use of multiple different feedback variables. For example, the current position provided by the encoder 232 and other motor 235 conditions, states, and/or properties of the motor 235 and/or components coupled to the motor 235 may also be fed back into the control loop of the motor control 220 as the feedback 224.

In an embodiment, the feedback 224 may be fed into a Luenberger observer 225 within the motor controller 220. The Luenberger observer 225 may be an algorithm that is capable of producing an estimate of the state of the stepper motor 235 system based on measurements of the input and output (e.g., the feedback 224) from the encoder 232 of the stepper motor 235. In an embodiment, the Luenberger observer 225 may take the form of any suitable state observer model. For example, in FIG. 2, the Luenberger observer 225 equations are based on a discrete time model. In an embodiment, any of the gain values Ã, \tilde{B}, \tilde{C}, \tilde{D}, or L (where L is the Luenberger gain value), may be modified in order to drive a particular convergence of the Luenberger observer 225 model to the state of the plant 222 in a desired manner. The output of the Luenberger observer 225 can then be fed into the control block 221, and the control loop may continue running.

In this way, a position and velocity vector x[n] can be generated and an encoder feedback measurement y[n] can be provided to the physical plant of the motor 235 (through the PWM converter 223 and the driver chip 231) instead of relying on the direct feedback of an input force to the physical plant, such as the motor 235. This allows for a conversion of the calculated input force into PWM signals that provide an instruction for a number of steps and an instruction for the direction of the steps. Further, the combination of the Luenberger observer 225 and the state space plant 222 allows for the approximation of a discrete model for a discontinuous physical system. Additionally, it is to be appreciated that the state space can allow for the control model to be applied to linear, non-linear, time-varying, and/or time-invariant systems. This is particularly beneficial to allow for more robust model generation, especially compared to PID control loop models that are limited to linear time-invariant (LTI) systems.

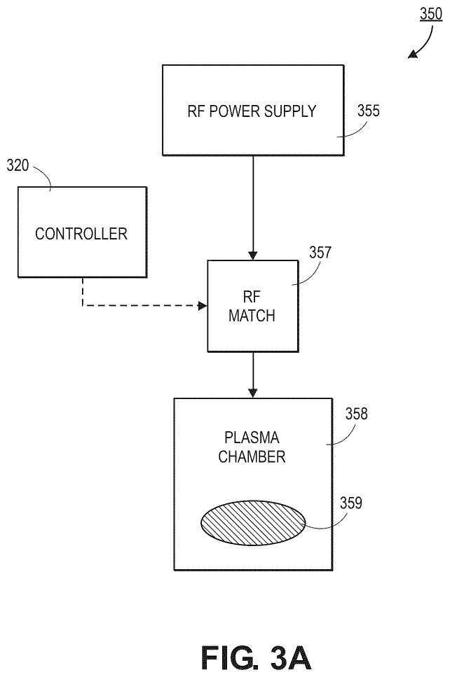

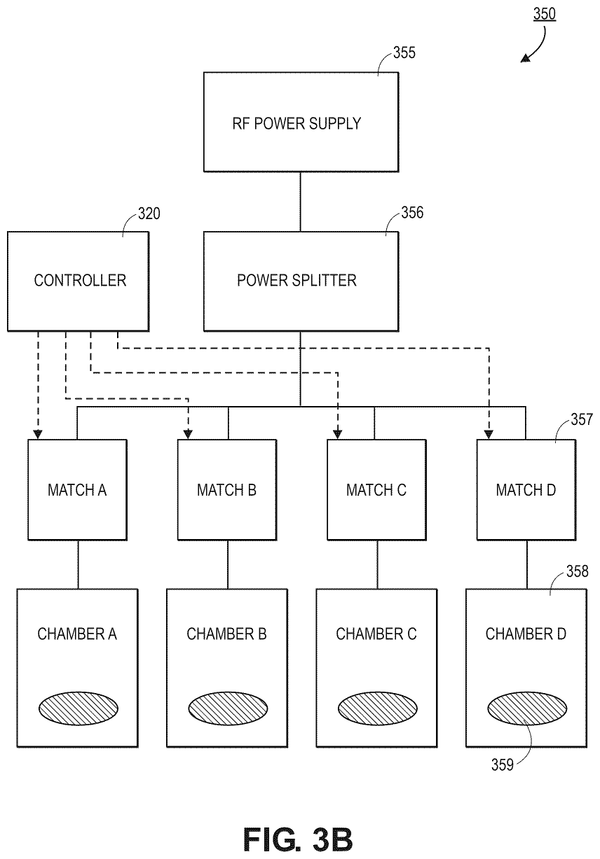

Referring now to FIG. 3A, a schematic illustration of a plasma processing tool 350 is shown, in accordance with an embodiment. In an embodiment, the plasma processing tool 350 may be an RF plasma processing tool. Though, the plasma processing tool 350 may also be a microwave plasma tool, or any other frequency plasma processing tool. The plasma processing tool 350 may include a power supply 355. In some embodiments, the power supply 355 may be an RF power supply. The power supply 355 may be electrically coupled to a plasma chamber 358 with electrical cabling or the like. In an embodiment, the plasma chamber 358 may be used for any suitable plasma process used to process a substrate 359 (e.g., a semiconductor wafer). For example, the plasma chamber 358 may be an etching chamber, a deposition chamber, a treatment chamber, or the like.

A variable impedance match 357 may be electrically coupled between the power supply 355 and the plasma chamber 358. The variable impedance match 357 allows for the impedance of the power supply 355 and/or any of the electrical cabling to be matched to a variable impedance of the plasma within the plasma chamber 358. For example, the impedance of the plasma may vary due to different processing conditions (e.g., pressures, gas flow rates, power settings, chamber geometry changes, etc.). The impedance of the variable impedance match 357 may be modulated by changing the capacitance value of one or more capacitors within the variable impedance match 357 and/or changing the inductance value of one or more inductors within the variable impedance match 357. The capacitances and/or inductances may be changed through the actuation of a stepper motor. The stepper motor may be an integrated portion of the variable impedance match 357.

In an embodiment, the stepper motor of the variable impedance match 357 may be controlled by a controller 320. In an embodiment, the controller 320 may be similar to the controller 220 described in greater detail herein. For example, the controller 220 may comprise a state space model with pole placement feedback and a Luenberger observer. In the illustrated embodiment, the controller 220 is operated to control a single variable impedance match 357. Though, in other embodiments, the controller 220 is scalable to operate multiple variable impedance matches 357, similar to the embodiment shown in FIG. 3B.

Referring now to FIG. 3B, a schematic illustration of a plasma processing tool 350 with multiple plasma chambers 358 is shown, in accordance with an embodiment. As shown, the plasma processing tool 350 may include a single power supply 355, and a power splitter 356 may be used to split the power towards a plurality of plasma chambers 358. For example, the plurality of plasma chambers 358 in FIG. 3B includes plasma chambers A-D. In an embodiment, each of the plasma chambers 358 may include a respective variable impedance match 357. A single controller 320 may be used in order to set the impedance of each of the variable impedance matches 357.

The controller 320 may be similar to the controller 220 described above with the addition of further scaling through the use of matrix math within the feedback model. Particularly, the use of a state space algorithm also allows for easy scaling through the use of matrix-based equations in order to control multiple stepper motors that are working in parallel with different motor dynamics. As such, a multi-chamber 358 plasma tool 350, such as the one shown in FIG. 3B, can have impedance matching implemented by a single controller 320.

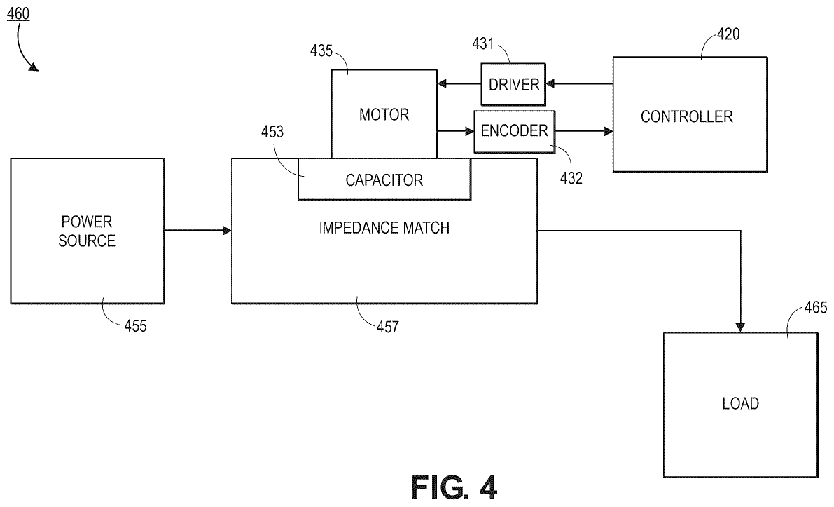

Referring now to FIG. 4, a schematic illustration of a power delivery system 460 is shown, in accordance with an embodiment. In an embodiment, the power delivery system 460 may include a power source 455 and a load 465. The power source 455 and the load 465 may be used for any type of process, such as plasma processes, communication systems, electrical signaling, and/or the like. In an embodiment, the impedance of the power source 455 may be matched to the impedance of the load 465 by an impedance match 457.

In an embodiment, the impedance match 457 may comprise a capacitor 453. The capacitor 453 may be a variable capacitor, and the capacitance of the capacitor 453 may be controlled by the actuation of a stepper motor 435. While a capacitor 453 is shown in FIG. 4, it is to be appreciated that any variable passive electrical component (e.g., inductor, resistor, etc.) can be used in the impedance match 457 in order to modify the impedance. In the illustrated embodiment, the stepper motor 435 is outside of the impedance match 457. Though, in other embodiments, the stepper motor 435 may be integrated into the impedance match 457.

In an embodiment, a controller 420 may be communicatively coupled to the stepper motor 435 (e.g., through a stepper motor driver 431 and an encoder 432). Though, in other embodiments the stepper motor driver 431 and/or the encoder 432 may be integrated with the stepper motor 435. The controller 420 may be similar to any of the controllers described in greater detail herein. For example, the controller may comprise a state space model with pole placement feedback and a Luenberger observer.

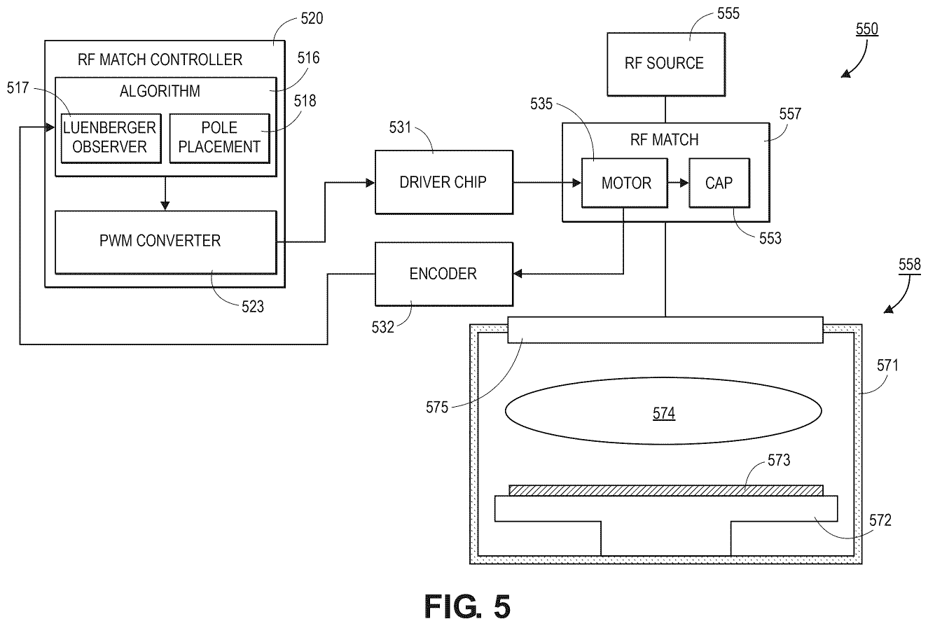

Referring now to FIG. 5, a schematic illustration of a plasma tool 550 is shown, in accordance with an embodiment. In an embodiment, the plasma tool 550 in FIG. 5 is similar to the plasma tool 350 in FIG. 3A. For example, the plasma tool 550 may include a power source 555 that is electrically coupled to a plasma chamber 558, and a variable impedance match 557 is electrically coupled between the power source 555 and the plasma chamber 558. In an embodiment, the plasma chamber 558 may comprise a chamber 571 that is capable of supporting a sub-atmospheric pressure (e.g., a vacuum environment). A lid 575 may be used to seal the chamber 571. In some embodiments, the lid 575 may be electrically coupled to the power source 555, and the lid 575 is used to couple the power into the chamber 571 in order to ignite a plasma 574. The plasma 574 may be used to process a substrate 573 that is supported on a pedestal 572 within the chamber 571. The pedestal 572 may be a chuck, such as an electrostatic chuck (ESC) or the like.

In an embodiment, the impedance match 557 may comprise an integrated stepper motor 535 that is used to control a capacitor 553 within the impedance match 557. While a single stepper motor 535 and capacitor 553 are shown in FIG. 5, embodiments may include an impedance match 557 with any number of stepper motors 535 and capacitors 553.

In an embodiment, the stepper motor 535 may be operated by a match controller 520. The match controller 520 may be similar to any of the controllers described in greater detail herein. In a particular embodiment, the match controller 520 may include a model or algorithm 516 that is stored on a memory (e.g., a non-transitory machine-readable medium) within the match controller 520. In an embodiment, the algorithm 516 may be a state space model with pole placement feedback 518 and a Luenberger observer 517. The match controller 520 may also comprise a PWM converter in order to provide PWM signals (e.g., a direction signal and a step count signal) to a driver chip 531. In an embodiment, an encoder 532 may provide position information of the stepper motor 535 as feedback to the algorithm 516 of the match controller 520.

In an embodiment, the match controller 520 may be implemented as an FPGA device. The use of an FPGA device allows for a cost-effective solution to implement custom hardware to efficiently run the state space model of the algorithm 516. In some instances, the PWM controller 523 may also be implemented as part of the FPGA device. The FPGA device may be communicatively coupled to a non-transitory machine-readable medium suitable for storing instructions for the algorithm 516 and/or data obtained from the encoder and/or generated by the algorithm 516.

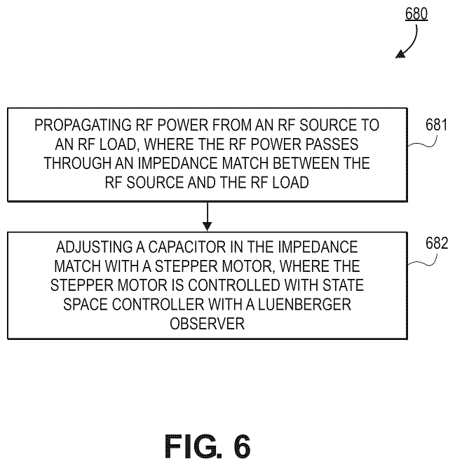

Referring now to FIG. 6, a flow diagram that depicts a process 680 for modifying an impedance of a plasma processing tool is shown, in accordance with an embodiment. In an embodiment, the plasma processing tool may be similar to any of the plasma processing tools described in greater detail herein. In an embodiment, the process 680 may begin with operation 681, which comprises propagating power (e.g., RF power) from a power source to a load. For example, the load may be a plasma within a plasma chamber. In an embodiment, the power passes through an impedance match that is electrically coupled between the power source and the load. In an embodiment, the impedance match may be similar to any of the impedance matches described in greater detail herein. For example, the impedance match may include one or more variable capacitors that are controlled by a stepper motor.

In an embodiment, the process 680 may continue with operation 682, which comprises adjusting the capacitor in the impedance match with the stepper motor. In an embodiment, the stepper motor is controlled with a state space controller that includes a Luenberger observer. In some embodiments, the state space controller may further include the use of pole placement feedback. Such a state space controller is capable of providing a continuous velocity curve to move the stepper motor from a first position to a second position. The continuous profile of the velocity curve allows for trajectories that have faster accelerations and higher velocities than are possible with the trapezoidal models. Particularly, the lack of discontinuities allows for a smoother performance. In contrast, the trapezoidal models rely on smaller accelerations and velocities in order to minimize the negative effects of the jerking conditions that arise from the discontinuities within the trajectory. Therefore, embodiments disclosed herein may be useful for high performance impedance matching use cases, such as in RF plasma systems.

Though, it is to be appreciated that the state space stepper motor controller may be used to control stepper motors for any suitable purpose. That is, the state space stepper motor controller may be used for systems other than impedance matching applications.

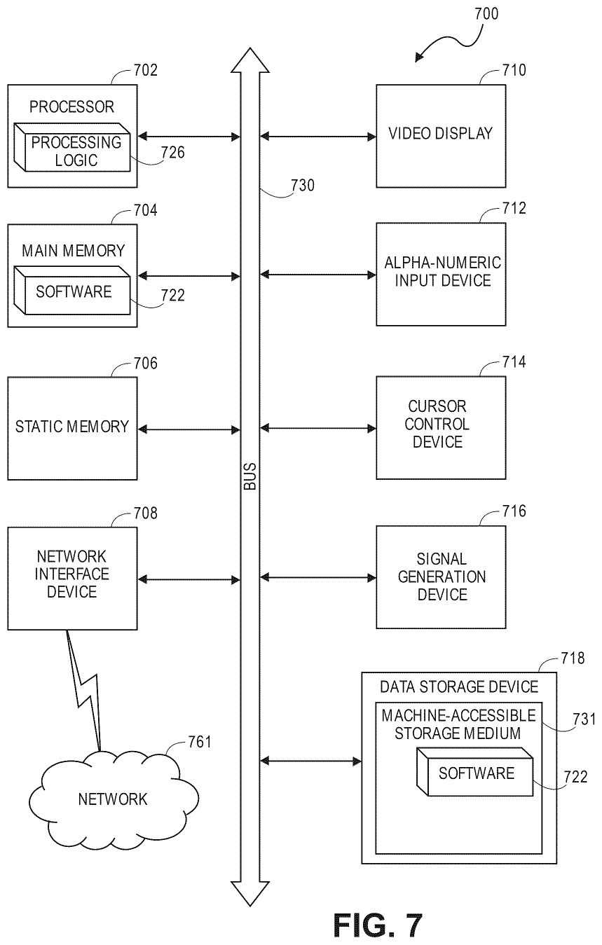

Referring now to FIG. 7, a block diagram of an exemplary computer system 700 of a processing tool is illustrated in accordance with an embodiment. In an embodiment, computer system 700 is coupled to and controls processing in the processing tool. Computer system 700 may be connected (e.g., networked) to other machines in a Local Area Network (LAN), an intranet, an extranet, or the Internet. Computer system 700 may operate in the capacity of a server or a client machine in a client-server network environment, or as a peer machine in a peer-to-peer (or distributed) network environment. Computer system 700 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 700, the term “machine” shall also be taken to include any collection of machines (e.g., computers) that individually or jointly execute a set (or multiple sets) of instructions to perform any one or more of the methodologies described herein.

Computer system 700 may include a computer program product, or software 722, having a non-transitory machine-readable medium having stored thereon instructions, which may be used to program computer system 700 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 700 includes a system processor 702, a main memory 704 (e.g., read-only memory (ROM), flash memory, dynamic random access memory (DRAM) such as synchronous DRAM (SDRAM) or Rambus DRAM (RDRAM), etc.), a static memory 706 (e.g., flash memory, static random access memory (SRAM), etc.), and a secondary memory 718 (e.g., a data storage device), which communicate with each other via a bus 730.

System processor 702 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 702 may also be one or more special-purpose processing devices such as an application specific integrated circuit (ASIC), a field programmable gate array (FPGA), a digital signal system processor (DSP), network system processor, or the like. System processor 702 is configured to execute the processing logic 726 for performing the operations described herein.

The computer system 700 may further include a system network interface device 708 for communicating with other devices or machines. The computer system 700 may also include a video display unit 710 (e.g., a liquid crystal display (LCD), a light emitting diode display (LED), or a cathode ray tube (CRT)), an alphanumeric input device 712 (e.g., a keyboard), a cursor control device 714 (e.g., a mouse), and a signal generation device 716 (e.g., a speaker).

The secondary memory 718 may include a machine-accessible storage medium 731 (or more specifically a computer-readable storage medium) on which is stored one or more sets of instructions (e.g., software 722) embodying any one or more of the methodologies or functions described herein. The software 722 may also reside, completely or at least partially, within the main memory 704 and/or within the system processor 702 during execution thereof by the computer system 700, the main memory 704 and the system processor 702 also constituting machine-readable storage media. The software 722 may further be transmitted or received over a network 761 via the system network interface device 708. In an embodiment, the network interface device 708 may operate using RF coupling, optical coupling, acoustic coupling, or inductive coupling.

While the machine-accessible storage medium 731 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

What is claimed is:

1. An apparatus, comprising:
a stepper motor;
a driver chip communicatively coupled to the stepper motor;
an encoder communicatively coupled to the stepper motor; and
a feedback controller communicatively coupled to the driver chip and the encoder, wherein the feedback controller comprises:
a state space plant configured to receive a control signal and generate a vector comprising a position and velocity of the stepper motor;
a pulse width modulation (PWM) converter configured to receive the vector and output a first PWM signal corresponding to a number of steps to drive the stepper motor and a second PWM signal corresponding to a direction of the number of steps of the stepper motor; and
a Luenberger observer configured to receive a feedback signal from the encoder.

2. The apparatus of claim 1, wherein one or more of the state space plant, the PWM converter, or the Luenberger observer is implemented with a field programmable gate array (FPGA).

3. The apparatus of claim 1, wherein state space gain values of the feedback controller are configured to control one or more of an acceleration, a peak velocity, a rise time, or a settling time of motion of the stepper motor.

4. The apparatus of claim 1, wherein the state space plant further comprises pole placement feedback that uses a mathematical technique to place a pole in the state space plant.

5. The apparatus of claim 4, wherein the mathematical technique uses an eigenvalue in order to place the pole in the state space plant.

6. The apparatus of claim 1, wherein the feedback controller is configured to change an angular position of the stepper motor from a first position to a second position with a continuous velocity curve.

7. The apparatus of claim 1, wherein the stepper motor is coupled to a variable capacitor.

8. The apparatus of claim 7, wherein the variable capacitor is part of an impedance match, and wherein the stepper motor is configured to control an impedance of the impedance match.

9. The apparatus of claim 8, wherein the impedance match is coupled to a plasma chamber.

10. The apparatus of claim 1, wherein the state space plant is configured to model a linear system, a non-linear system, a time-varying, and/or a time-invariant system.

11. An apparatus, comprising:
a plasma chamber;
a power source electrically coupled to the plasma chamber;
an impedance match with a variable passive electrical component, wherein the impedance match is electrically coupled between the plasma chamber and the power source; and
a stepper motor coupled to the variable passive electrical component, wherein the stepper motor is configured to be controlled by a motor controller, and wherein the motor controller comprises a feedback control algorithm with a state space plant with a Luenberger observer.

12. The apparatus of claim 11, wherein the state space plant further comprises pole placement feedback.

13. The apparatus of claim 11, wherein the motor controller further comprises a pulse width modulation (PWM) converter.

14. The apparatus of claim 11, wherein the motor controller further comprises an encoder to provide feedback to the feedback control algorithm.

15. The apparatus of claim 11, further comprising:
a driver chip between the motor controller and the stepper motor.

16. The apparatus of claim 11, wherein the power source is an RF power source.

17. The apparatus of claim 11, wherein the plasma chamber is one of a plurality of plasma chambers, and the impedance match is one of a plurality of impedance matches, wherein each impedance match is coupled to one of a plurality of stepper motors, and wherein the apparatus further comprises:
a power splitter electrically coupled between the power source and the plurality of impedance matches, and wherein the motor controller is communicatively coupled to each of the plurality of stepper motors.

18. An apparatus, comprising:
a field programmable gate array (FPGA) configured to implement a state space plant configured to receive a control signal and generate a vector comprising a position and a velocity of a stepper motor, wherein the state space plant is fed a feedback input that is informed by a Luenberger observer that is stored in a non-transitory machine-readable medium coupled to the FPGA; and
a pulse width modulation (PWM) converter electrically coupled to the FPGA, wherein the PWM converter is configured to receive the vector and output a first PWM signal corresponding to a number of steps to drive the stepper motor and a second PWM corresponding to a direction of the number of steps of the stepper motor.

19. The apparatus of claim 18, wherein the state space plant further comprises pole placement feedback.

20. The apparatus of claim 18, wherein the state space plant is configured to control the stepper motor that is electrically coupled to the PWM converter.
